(19) United States
(12) Patent Application Publication
(10) Pub. No.: US 2023/0337508 A1
(43) Pub. Date: Oct. 19, 2023

(54) DISPLAY DEVICE AND WEARABLE DEVICE INCLUDING THE SAME

(71) Applicant: Samsung Display Co., LTD., Yongin-si (KR)

(72) Inventors: Sang Ho KIM, Yongin-si (KR); Soo Min BAEK, Yongin-si (KR); Ju Youn SON, Yongin-si (KR); Ji Won LEE, Yongin-si (KR); Cheon Myeong LEE, Yongin-si (KR); Bek Hyun LIM, Yongin-si (KR); Ju Hwa HA, Yongin-si (KR)

(21) Appl. No.: 18/129,319

(22) Filed: Mar. 31, 2023

(30) Foreign Application Priority Data
Apr. 14, 2022 (KR) 10-2022-0046175

(51) Int. Cl. H10K 59/80

(52) U.S. Cl. CPC H10K 59/879

(57) ABSTRACT

A display device includes a display panel which displays an image on an image display surface thereof, at least one lens frame disposed on the image display surface to refract image display lights, and at least one multi-channel lens which forms exit paths of the image display lights refracted by the at least one lens frame for each of multiple channels.

This application claims priority to Korean Patent Application No. 10-2022-0046175, filed on Apr. 14, 2022, and all the benefits accruing therefrom under 35 U.S.C. §119, the content of which in its entirety is herein incorporated by reference.

### BACKGROUND

### 1. Field

The disclosure relates to a display device and a wearable device including the display device.

### 2. Description of the Related Art

Display devices become more and more important as multimedia technology evolves. Accordingly, a variety of types of display devices such as liquid-crystal display (LCD) devices and organic light-emitting display (OLED) devices are currently used in various fields.

Among display devices, there are electronic devices that can be worn on a person’s body. Such electronic devices are typically referred to as wearable devices. A wearable electronic device can be worn directly on a person’s body, and thus portability and user accessibility can be improved.

An example of such wearable electronic devices may include ahead mounted display (or a head mounted electronic device) that can be mounted on a person’s head. Head mounted displays (HMD) may be roughly sorted into a see-through head mounted display which provides augmented reality (AR) and a see-closed head mounted display which provides virtual reality (VR).

### SUMMARY

Embodiments of the disclosure provide a display device that can prevent image display defects and can improve image display quality, and a wearable device including the display device.

According to an embodiment of the disclosure, a display device includes a display panel which displays an image on an image display surface thereof, at least one lens frame disposed on the image display surface, where the at least one lens frame refracts image display lights emitted from the image display surface, and at least one multi-channel lens which forms exit paths of the image display lights refracted by the at least one lens frame for each of multiple channels.

In an embodiment, the at least one lens frame may include first and second lens frames disposed in line with positions of a user’s left and right eyes, respectively, and the first and second lens frames may refract the image display lights output from the image display surface of the display panel toward a front side at a predetermined angle in an outward direction or toward an outer periphery to output the image display lights to rear surfaces of the first and second multi-channel lenses.

In an embodiment, the at least one multi-channel lens may include first and second multi-channel lenses disposed in line with the first and second lens frames, respectively, and wherein the first and second multi-channel lenses pass the image display lights refracted by the first and second lens frames through different paths for the multiple channels, to transmit the image display lights to a user’s left and right eyes through channels of the different paths.

In an embodiment, each of the first and second lens frames may include a lens sheet having an area and a shape corresponding to the image display surface of the display panel; and a plurality of optical lenses disposed on a front surface of the lens sheet, where the plurality of optical lenses may refract the image display lights passed through the lens sheet in an outward direction or toward an outer periphery of the lens sheet to output the image display lights.

In an embodiment, the plurality of optical lenses may be in a ring type having different circumferences from each other, and the plurality of optical lenses may be arranged in the form of a plurality of concentric circles on the front surface of the lens sheet to cover the front surface of the lens sheet.

In an embodiment, one or more structural characteristics of length, area, and width of adjacent optical lenses of the plurality of optical lenses may be different from each other.

In an embodiment, each of the plurality of optical lenses may have a convex protruding cross-section, and a highest point or thickest point of the convex protruding cross-section may be disposed at a position inclined at a first angle from a front vertical direction in the outward direction or toward the outer periphery.

In an embodiment, each of the plurality of optical lenses may be in a bar type and disposed to cover the front surface of the lens sheet, and the plurality of optical lenses may be arranged in parallel in a diagonal direction with respect to a center of the lens sheet in first to fourth divided areas of the lens sheet.

In an embodiment, the plurality of optical lenses may include a plurality of first optical lenses each having a convex protruding cross-section shaped in a way such that a highest point or a thickest point of the convex protruding cross-section is disposed at a position inclined at a first angle, and a plurality of second optical lenses each having a convex protruding cross-section shaped in a way such that a highest point or a thickest point of a convex cross-section is not inclined on the front side.

In an embodiment, each of the plurality of optical lenses may be in a bar type and disposed to cover the front surface of the lens sheet, and the plurality of optical lenses may be arranged in parallel in a horizontal or vertical stripes in first to fourth divided areas of the lens sheet.

In an embodiment, the plurality of optical lenses may include a plurality of first optical lenses each having a convex protruding cross-section shaped in a way such that a highest point or a thickest point of the convex protruding cross-section is disposed at a position inclined at a first angle, a plurality of second optical lenses each having a convex protruding cross-section shaped in a way such that a highest point or a thickest point of the convex protruding cross-section is not inclined on the front side, and a plurality of third optical lenses each having a convex protruding cross-section shaped in a way such that a highest point or a thickest point of the convex protruding cross-section is disposed at a position inclined at a second angle different from the first angle.

In an embodiment, each of the first and second lens frames may include a flat light-transmitting film including a plurality of reflective partition walls or a plurality of reflective bonding surfaces inclined at a predetermined angle, and each of the first and second lens frames may refract or reflect the image display lights incident on a rear surface in the outward direction or toward the outer periphery from a center according to inclinations of the plurality of reflective partition walls or the plurality of reflective bonding surfaces.

In an embodiment, a plurality of reflective partition walls or the plurality of reflective bonding surfaces may be in a ring type having different circumferences from each other, and the plurality of reflective partition walls or the plurality of reflective bonding surfaces may be arranged in a plurality of concentric circles inside the light-transmitting film.

In an embodiment, one or more structural characteristics of spacing, length, thickness, area and width of the plurality of reflective partition walls or the plurality of reflective bonding surfaces are different from one another .

In an embodiment, the plurality of reflective partition walls or the plurality of reflective bonding surfaces may be inclined at a first angle in the outward direction or toward the outer periphery from the front vertical direction to refract the image display lights.

In an embodiment, the plurality of reflective partition walls or the plurality of reflective bonding surfaces may be in a straight bar type and the plurality of reflective partition walls or the plurality of reflective bonding surfaces may be arranged in parallel in a diagonal direction parallel with respect to a center in first to fourth divided areas of the light-transmitting film.

In an embodiment, the plurality of reflective partition walls may include a plurality of first partition walls inclined at a first angle from a front vertical direction to an outward direction, and a plurality of second partition walls disposed vertically such that plurality of second partition walls is not inclined from the front vertical direction.

In an embodiment, the plurality of reflective partition walls or the plurality of reflective bonding surfaces may be in a straight bar type and the plurality of reflective partition walls or the plurality of reflective bonding surfaces may be arranged in horizontal or vertical stripes in each of first to fourth divided areas of the light-transmitting film.

In an embodiment, the plurality of reflective partition walls may include a plurality of first partition walls inclined at a first angle from a front vertical direction toward the outer periphery, a plurality of second partition walls disposed vertically such that the plurality of second partition walls are not inclined from the front vertical direction, and a plurality of third partition walls inclined at a second angle from the front vertical direction toward the outer periphery.

According to an embodiment of the disclosure, a wearable device comprising a main frame mounted on a user’s body, a display device mounted on the main frame, where the display device displays an image, and a cover frame covering the display device, where the display device includes a display panel which displays an image on an image display surface thereof, at least one lens frame disposed on the image display surface, where the at least one lens frame refracts image display lights, and at least one lens which forms exit paths of the image display lights refracted by the at least one lens frame for each of multiple channels.

According to embodiments of the disclosure, image display defects such as a ghost image in a display device and a wearable device including display device may be effectively prevented, so that user satisfaction and reliability may be improved.

It should be noted that effects of the disclosure are not limited to those described above and other effects of the disclosure will be apparent to those skilled in the art from the following descriptions.

### BRIEF DESCRIPTION OF THE DRAWINGS

The above and other features of the disclosure will become more apparent by describing in detail embodiments thereof with reference to the attached drawings, in which:

FIG. 1 is an exploded perspective view showing a display device according to an embodiment and a wearable device including the same.

FIG. 2 is a front view showing the display panel and the lens frame disposed on the front side of the display panel shown in FIG. 1.

FIG. 3 is a cross-sectional view showing a cut surface of the lens frame shown in FIG. 2, taken along line I - I′.

FIG. 4 is a cross-sectional view showing another example of the lens frame shown in FIG. 2, taken along line I - I′.

FIG. 5 is a front view showing the display panel and the multi-channel lenses disposed on the front surface of the lens frame shown in FIG. 1.

FIGS. 6A and 6B are perspective views showing one side and the opposite side of a multi-channel lens shown in FIGS. 1 and 5.

FIG. 7 is a front view showing mirror-coated parts of the multi-channel lens shown in FIGS. 6A and 6B in detail.

FIG. 8 is a perspective view of the rear side of the mirror-coated parts of the multi-channel lens shown in FIGS. 6A and 6B in detail.

FIG. 9 is an exploded perspective view showing the structure that the display panel, the lens frame and the multi-channel lens shown in FIGS. 1 and 5 are disposed and coupled with one another.

FIG. 10 is a cross-sectional view showing in detail the display device shown in FIG. 5, taken along line A - A′.

FIG. 11 is a view showing an image displayed on a display panel when a user’s pupil is located at the center.

FIG. 12 is a view showing a virtual reality (VR) image recognized by the user when a user’s pupil is located at the center.

FIG. 13 is a cross-sectional view for illustrating display paths of ghost images in a display device and the causes.

FIG. 14 is a graph for illustrating refraction angles of image display lights according to the lens frame structure of FIGS. 3 and 4.

FIG. 15 is a cross-sectional view showing the refraction angles of image display lights and display paths according to the lens frame structure of FIGS. 3 and 4.

FIG. 16 is a front view showing a structure of a lens frame according to another embodiment of the disclosure.

FIG. 17 is a cross-sectional view showing an example of the lens frame shown in FIG. 16, taken along line B - B′.

FIG. 18 is a cross-sectional view showing another example of the lens frame shown in FIG. 16, taken along line B - B′.

FIG. 19 is a front view showing a structure of a lens frame according to yet another embodiment of the disclosure.

FIG. 20 is a cross-sectional view showing an example of the lens frame shown in FIG. 19, taken along line C - C′.

FIG. 21 is a cross-sectional view showing another example of the lens frame shown in FIG. 19, taken along line C - C′.

### DETAILED DESCRIPTION

The invention will now be described more fully hereinafter with reference to the accompanying drawings, in which various embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present invention. Similarly, the second element could also be termed the first element.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element’s relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Each of the features of the various embodiments of the disclosure may be combined or combined with each other, in part or in whole, and technically various interlocking and driving are possible. Each embodiment may be implemented independently of each other or may be implemented together in an association.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ± 30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described in detail with reference to the accompanying drawings.

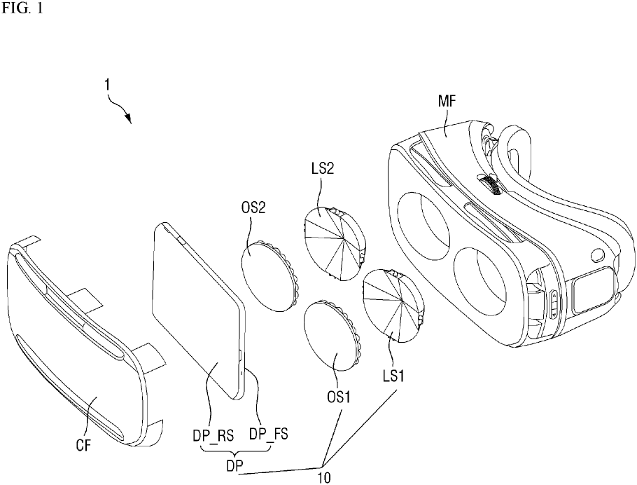

FIG. 1 is an exploded perspective view showing a display device according to an embodiment and a wearable device including the display device.

In an embodiment, a display device 10 may be formed with a wearable device 1 so that a user can carry the display device 10 and can easily wear on or take off the display device 10 from her/his face or head. Alternatively, the display device 10 may be assembled with the wearable device 1. The wearable device 1 may be implemented in the form of glasses or a head mount, and may provide images to the user using the display device 10.

An embodiment of the wearable device 1 may include a see-through device that provides augmented reality based on actual external objects, and a see-closed device that provides virtual reality to a user using a screen independent of external objects. In the following description, embodiments where the wearable device 1 is a see-closed head mounted display device will be described in detail for convenience of description. It should be understood that the disclosure is not limited thereto.

Referring to FIG. 1, an embodiment of the wearable device 1 may include a main frame MF mounted on a user’s body, a display device 10 mounted on the main frame MF to display images, and a cover frame CF covering the display device 10.

The display device 10 includes a display panel DP for displaying images, first and second lens frames OS1 and OS2 that refract image display light, and first and second multi-channel lenses LS1 and LS2 for forming light paths so that the user can see the image display light from the display panel DP.

The main frame MF may be worn on a user’s face and head. The main frame MF may have a shape conforming to the shape of the user’s head and face.

The display device 10, i.e., the display panel DP, the first and second lens frames OS1 and OS2, and the first and second multi-channel lenses LS1 and LS2 may be formed together with the main frame MF. Alternatively, the display panel DP, the first and second lens frames OS1 and OS2, and the first and second multi-channel lenses LS1 and LS2 may be assembled and mounted on the main frame MF. In such an embodiment, the main frame MF may have space or structure in which the display panel DP, the first and second lens frames OS1 and OS2, and the first and second multi-channel lenses LS1 and LS2 are accommodated. Although not shown in the drawings, the main frame MF may further include a structure such as a strap and a belt for easy mounting. The main frame MF may further include a controller, an image processing unit, lens slots, etc.

The display panel DP may be divided into a front surface DP_FS on which images are displayed, and a rear surface DP_RS opposite to the front surface DP_FS. Image display light may be output through the front surface DP_FS of the display panel DP. As will be described later, the first and second lens frames OS1 and OS2 may be disposed on the front surface DP_FS of the display panel DP, and the first and second multi-channel lenses LS1 and LS2 may be disposed on the front surface of the first and second lens frames OS1 and OS2. In an embodiment, although not shown in the drawings, at least one infrared camera may be further disposed on at least one of the front surface DP_FS and the rear surface DP_RS of the display panel DP.

The display panel DP may be incorporated into the main frame MF with the first and second lens frames OS1 and OS2 and the first and second multi-channel lenses LS1 and LS2 mounted and fixed thereto, or may be detachably assembled to the main frame MF. The display panel DP may be opaque, transparent or translucent depending on the design of the display device 10, for example, the usage type of the display device 10.

The display panel DP may be a light-emitting display panel including light-emitting elements. In an embodiment, for example, the display panel DP may be an organic light-emitting display panel using organic light-emitting diodes, a micro light-emitting diode display panel using micro LEDs, a quantum-dot light-emitting display panel using quantum-dot light-emitting diodes, or an inorganic light-emitting display panel using inorganic light-emitting elements. In the following description, embodiments where the display panel DP is an organic light-emitting display panel will be described in detail for convenience of description. It should be understood, however, that the disclosure is not limited thereto.

The first and second lens frames OS1 and OS2 may have an area equal to an image display surface of the display panel DP and may be formed in a shape conforming to the image display surface. In addition, the first and second lens frames OS1 and OS2 may be formed to have the area and the shape corresponding to the shape of the rear surfaces of the first and second multi-channel lenses LS1 and LS2, respectively. The rear surfaces of the first and second lens frames OS1 and OS2 are attached to the image display surface of the display panel DP, and the first and second multi-channel lenses LS1 and LS2 are attached to the front surfaces of the first and second lens frames OS1 and OS2, respectively. The first and second lens frames OS1 and OS2 refract the image display light output from the image display surface of the display panel DP at a predetermined angle to provide the image display light to the first and second multi-channel lenses LS1 and LS2 on the front side.

In an embodiment, the first and second lens frames OS1 and OS2 refract the image display lights output from the image display surface of the display panel DP on the front side in the outward direction (or toward the outer periphery) relative to the front side, to provide the image display lights to the first and second multi-channel lenses LS1 and LS2 disposed on the front side. In such an embodiment, the first and second lens frames OS1 and OS2 refract the image display lights incident on the rear surface in the outward direction (or toward the outer periphery) to provide the image display lights to the rear surface of the first and second multi-channel lenses LS1 and LS2, respectively. The refraction angle or the radiation angle of each of the first and second lens frames OS1 and OS2 in the outward direction may be predetermined to be in a range of about 1 degree (1°) to about 30 degrees (30°). The structure and refraction angle of each of the first and second lens frames OS1 and OS2 will be described in greater detail later with reference to the accompanying drawings.

The first and second multi-channel lenses LS1 and LS2 form paths of light output through the first and second lens frames OS1 and OS2 so that a user can see the image display light on the front side.

The first and second multi-channel lenses LS1 and LS2 may provide a plurality of channels (or paths) through which the image display light output from the display panel DP passes. The plurality of channels may pass the image display light output from the display panel DP through different paths to provide it to the user. The image display light output through the first and second lens frames OS1 and OS2 may be incident on the channels, and an image enlarged through the channels may be focused on the user’s eyes.

The first and second multi-channel lenses LS1 and LS2 may be arranged on the front side of the first and second lens frames OS1 and OS2 so that the first and second multi-channel lenses LS1 and LS2 are in line with the positions of the user’s left and right eyes, respectively. The first and second multi-channel lenses LS1 and LS2 may be accommodated in the main frame MF.

The first and second multi-channel lenses LS1 and LS2 may refract and reflect the image display light output through the first and second lens frames OS1 and OS2 at least once to form paths to the user’s eyes. At least one infrared light source may be further disposed on one side of the main frame MF or each of the first and second multi-channel lenses LS1 and LS2 facing the user’s eyeballs.

The cover frame CF may be disposed on the side of the rear surface DP_RS of the display panel DP to cover the display panel DP so that the display panel DP can be protected. The cover frame CF may cover the display panel DP to be mounted on the main frame MF.

Although not shown in the drawings, the display device 10 may further include a controller for controlling the overall operation of the display device 10 including the display panel DP. The controller may control an image display operation of the display panel DP, an audio device, etc.

In an embodiment, the controller may perform image processing (e.g., image mapping) based on the image display paths and magnifications by the first and second lens frames OS1 and OS2 and the first and second multi-channel lenses LS1 and LS2, and may control so that the mapped image is displayed on the display panel DP. The controller may be implemented as a dedicated processor including an embedded processor and/or a general-purpose processor including a central processing unit or an application processor. It should be understood that the disclosure is not limited thereto.

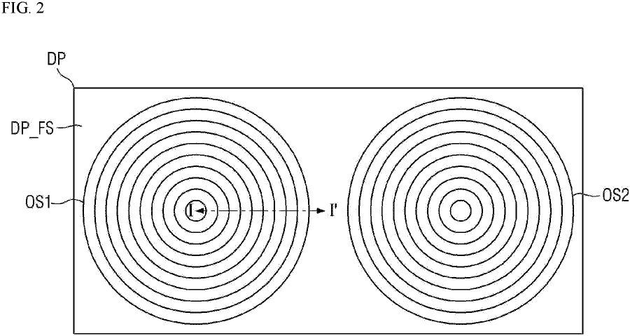

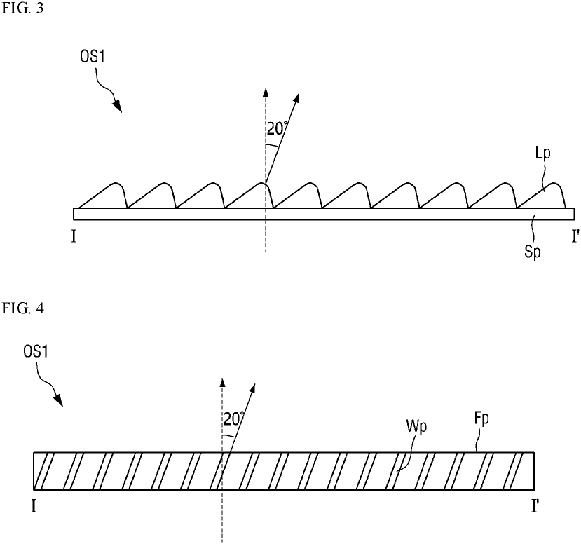

FIG. 2 is a front view showing the display panel and the lens frame disposed on the front side of the display panel shown in FIG. 1. FIG. 3 is a cross-sectional view showing a cut surface of the lens frame shown in FIG. 2, taken along line I - I′.

Referring to FIGS. 2 and 3, each of the first and second lens frames OS1 and OS2 includes a lens sheet Sp and a plurality of optical lenses Lp.

In an embodiment, the lens sheet Sp may have an area corresponding to the image display surface of the display panel DP and may be formed in the shape conforming to the image display surface. The lens sheet Sp may be implemented as (e.g., formed of or defined by) a flat transparent film, and may have a predetermined refractive index determined depending on the material of the film. The lens sheet Sp may be formed in a size and shape to cover the image display surface of the display panel DP. An adhesive material may be provided or formed on at least one of the front and rear surfaces of the lens sheet Sp.

The plurality of optical lenses Lp may be disposed on the front surface of the lens sheet Sp and may refract the image display lights passed through the lens sheet Sp in an outward direction (or toward the outer periphery) of the lens sheet Sp so that the light exits. The optical lenses Lp may be formed in ring shapes having different outer periphery lengths from each other, and may be arranged in the form of a plurality of concentric circles on the front surface of the lens sheet Sp to cover the front surface of the lens sheet Sp substantially completely. One or more structural characteristics, such as the length, the area, the width in at least one direction of each of the ring-type optical lenses Lp may be formed differently between adjacent optical lenses Lp. The cross section of each of the plurality of optical lenses Lp may be formed in a convex protruding shape, e.g., a hemispherical shape, so that the image display light incident through the lens sheet Sp on the rear side may be radially emitted on the front side.

In an embodiment, referring to FIG. 3, each of the plurality of optical lenses Lp may be formed or shaped in a way such that the highest point (or the thickest point) of the cross section thereof is located at the position that is inclined from the front vertical direction (the dotted arrow) at a first angle (e.g., about 20°) in the outward direction, that is, the highest point is located at the position a direction of which from a center of the lower surface is inclined from the front vertical direction at the first angle. In such an embodiment, the thickest point of the cross section of each of the plurality of optical lenses Lp is located at the point that is inclined by the predetermined first angle with respect to the front vertical direction (the dotted arrow) toward the outer periphery of the lens sheet Sp. Due to the cross-sectional shape and the inclination angle of each optical lens Lp, each optical lens Lp may refract the image display light by the first angle to output the image display light toward the outer periphery of the lens sheet Sp.

FIG. 4 is a cross-sectional view showing another example of the lens frame shown in FIG. 2, taken along line I - I′.

Referring to FIG. 4, in an embodiment, each of the first and second lens frames OS1 and OS2 may be implemented as a flat light-transmitting film Fp that includes a plurality of reflective partition walls Wp or a plurality of reflective bonding surfaces inclined at a predetermined angle. The light-transmitting film Fp may refract and reflect the image display lights incident on the rear side in the outward direction (or toward the outer periphery) according to the refractive index depending on its material and the inclinations of the plurality of reflective partition walls Wp or the reflective bonding surfaces to output the image display lights.

In such an embodiment, the plurality of reflective partition walls Wp or the plurality of reflective bonding surfaces included in the light-transmitting film Fp may be formed in a ring type with different circumferences of circles, so that the plurality of reflective partition walls Wp or the plurality of reflective bonding surfaces may be arranged inside the light-transmitting film Fp in the form of a plurality of concentric circles. One or more structural characteristics, such as the spacing, length, thickness, area or width, of the ring-type reflective partition walls Wp or the reflective bonding surfaces may be variously determined.

In an embodiment, referring to FIG. 4, the plurality of reflective partition walls Wp or the plurality of reflective bonding surfaces may be inclined at a first angle (e.g., about 20°) in the outward direction from the front vertical direction (the dotted arrow). In such an embodiment, the plurality of reflective partition walls Wp or the plurality of reflective bonding surfaces may be inclined at the predetermined first angle in the outward direction with respect to the front vertical direction (the dotted arrow). The first and second lens frames OS1 and OS2 may refract image display lights at the first angle in the outward direction according to the inclination angle and spacing of the plurality of first partition walls or the plurality of reflective bonding surfaces.

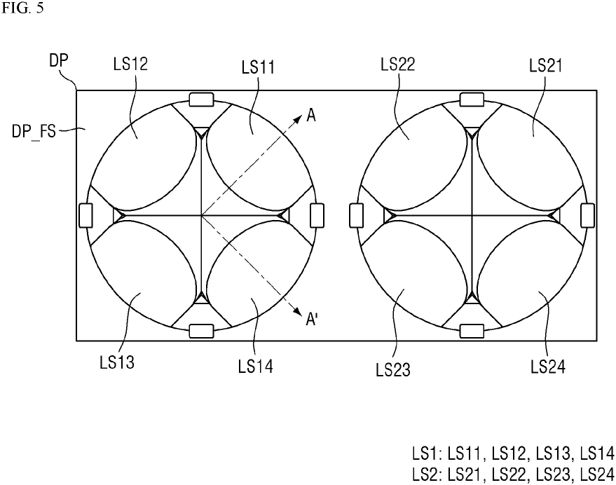

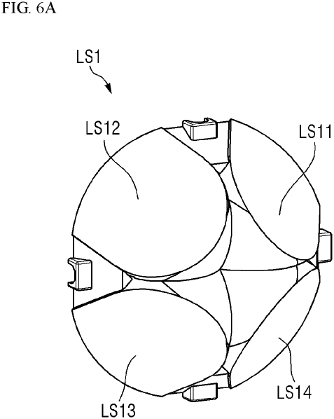

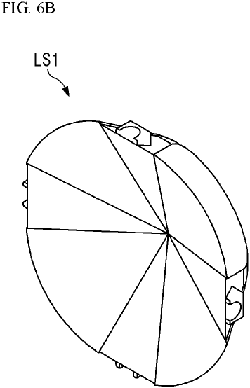

FIG. 5 is a front view showing the display panel and the multi-channel lenses disposed on the front surface of the lens frame shown in FIG. 1. FIGS. 6A and 6B are perspective views showing one side and the opposite side of a multi-channel lens shown in FIGS. 1 and 5.

Referring to FIGS. 5, 6A and 6B, the first and second multi-channel lenses LS1 and LS2 may be disposed on the front surfaces of the first and second lens frames OS1 and OS2, respectively, such that the first and second multi-channel lenses LS1 and LS2 are located in line with the user’s eyes, respectively. In an embodiment, for example, the display panel DP may have a substantially rectangular shape elongated in the left-right direction (horizontal direction in FIG. 5) when viewed from the front, and the first multi-channel lens LS1 may be disposed on the first lens frame OS1 on one side of the front surface of the display panel DP, i.e., on the front surface of the first lens frame OS1. In addition, the second multi-channel lens LS2 may be disposed on the second lens frame OS2 on the opposite side on the front surface of the display panel DP, i.e., on the front surface of the second lens frame OS2.

According to an embodiment of the disclosure, the first and second multi-channel lenses LS1 and LS2 may be disposed symmetrically with respect to a center of the display panel DP, and the first and second multi-channel lenses LS1 and LS2 may have substantially a same or similar structure as each other. It should be understood, however, that the disclosure is not limited thereto.

The first multi-channel lens LS1 may include a plurality of subsidiary lenses LS11, LS12, LS13 and LS14, and the second multi-channel lens LS2 may include a plurality of subsidiary lens LS21, LS22, LS23 and LS24.

According to an embodiment of the disclosure, the first multi-channel lens LS 1 may include a first subsidiary lens LS11, a second subsidiary lens LS12, a third subsidiary lens LS13 and a fourth subsidiary lens LS14. The second multi-channel lens LS2 may include a fifth subsidiary lens LS21, a sixth subsidiary lens LS22, a seventh subsidiary lens LS23, and an eighth subsidiary lens LS24. It should be noted that the number of the plurality of subsidiary lenses LS11, LS12, LS13, LS14, LS21, LS22, LS23 and LS24 is not limited thereto.

According to an embodiment of the disclosure, since the second multi-channel lens LS2 is substantially identical to or similar to the first multi-channel lens LS1. Therefore, the following description will focus on the first multi-channel lens LS1.

The first multi-channel lens LS1 shown in FIG. 5 may have a generally circular shape when viewed from the front. The first subsidiary lens LS11, the second subsidiary lens LS12, the third subsidiary lens LS13 and the fourth subsidiary lens LS14 may be arranged such that they surround the center of the circle when viewed from the front, for example, in a clover shape. In an embodiment, for example, as shown in FIG. 5, the first subsidiary lens LS11, the second subsidiary lens LS12, the third subsidiary lens LS13 and the fourth subsidiary lens LS14 may be disposed at the upper right end, the upper left end, the lower left end and the lower right end of the center of the first multi-channel lens LS1. The first subsidiary lens LS11, the second subsidiary lens LS12, the third subsidiary lens LS13 and the fourth subsidiary lens LS14 may be connected with one another as a single piece (or integrally formed with one another as a single unitary and indivisible part), or may be separated from one another.

More specifically, FIG. 6A is a perspective view showing one side of the first multi-channel lens LS1 which faces a user’s eye. FIG. 6B is a perspective view showing the opposite side of the first multi-channel lens LS1 which faces the image display surface of the display panel DP.

Referring to FIGS. 6A and 6B, in an embodiment, the cross-section of the first multi-channel lens LS1 may be formed in a generally hemispherical shape. In such an embodiment, one side of the first multi-channel lens LS1 which faces the main frame MF or a user’s eye may be formed in a convex shape, and the opposite side of the first multi-channel lens LS1 which faces the display panel DP may be formed in a concave shape.

The second multi-channel lens LS2 may also have a generally hemispherical cross-section, and the fifth subsidiary lens LS21, the sixth subsidiary lens LS22, the seventh subsidiary lens LS23 and the eighth subsidiary lens LS24 may be disposed in a circular shape or a clover shape surrounding the center of the second multi-channel lens LS2 when viewed from the front.

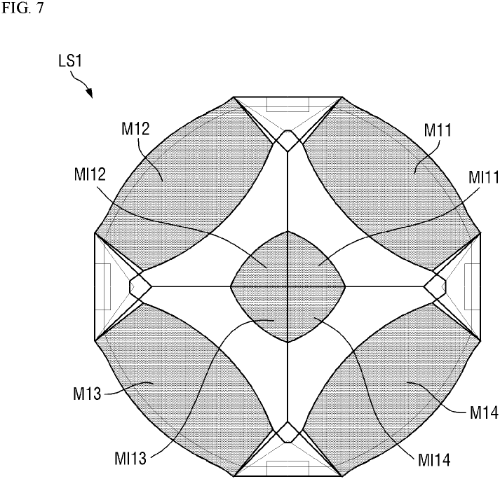

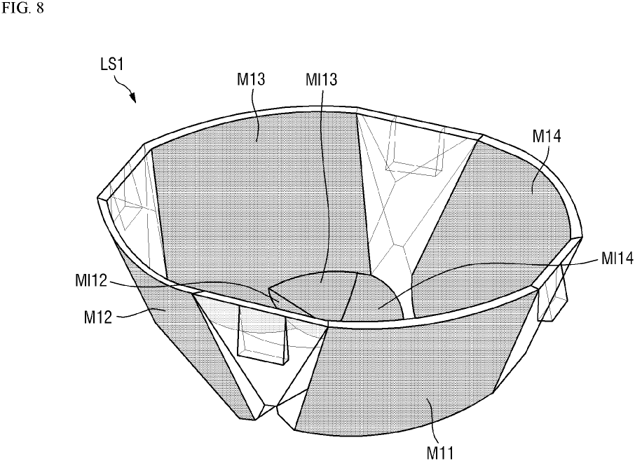

FIG. 7 is a front view showing mirror-coated parts of the multi-channel lens shown in FIGS. 6A and 6B in detail. FIG. 8 is a perspective view of the rear side of the mirror-coated parts of the multi-channel lens shown in FIGS. 6A and 6B in detail.

Referring to FIGS. 7 and 8, in an embodiment, the front surfaces or the rear surfaces of the first to fourth subsidiary lenses LS11, LS12, LS13 and LS14 formed in the first multi-channel lens LS1 may be the mirror-coated parts. Accordingly, a reflective material may be formed or coated on the first to fourth mirror-coated parts M11, M12, M13 and M14 which are separately defined on the first to fourth subsidiary lenses LS11, LS12, LS13 and LS14, respectively.

The first to fourth mirror-coated parts M11, M12, M13 and M14 separately formed on the first to fourth subsidiary lenses LS11, LS12, LS13 and LS14, respectively, face the central portion of the first multi-channel lens LS1, i.e., the concaved portion of the first multi-channel lens LS1. Accordingly, the first to fourth mirror-coated parts M11, M12, M13 and M14 may reflect the image display light incident from the rear surface of the first multi-channel lens LS1 toward the concaved portion that is the central portion of the first multi-channel lens LS1.

In such an embodiment, first to fourth inner coated parts MI11, MI12, MI13 and MI14 are defined on the concaved portion that is the central portion of the first multi-channel lens LS 1 and is also the rear surface of the first multi-channel lens LS1, which face the first to fourth mirror-coated parts M11, M12, M13 and M14. A reflective material is formed or coated on the first to fourth inner coated parts MI11, MI12, MI13 and MI14, like the first to fourth mirror-coated parts M11, M12, M13 and M14. Accordingly, the first to fourth inner coated parts MI11, MI12, MI13 and MI14 may reflect the image display lights reflected from the first to fourth mirror-coated parts M11, M12, M13 and M14 toward the user’s eyes on the front side.

The features of the first to fourth mirror-coated parts M11, M12, M13 and M14 and the first to fourth inner coated parts MI11, MI12, MI13 and MI14 of the first multi-channel lens LS1 may be equally applied to the second multi-channel structure LS2.

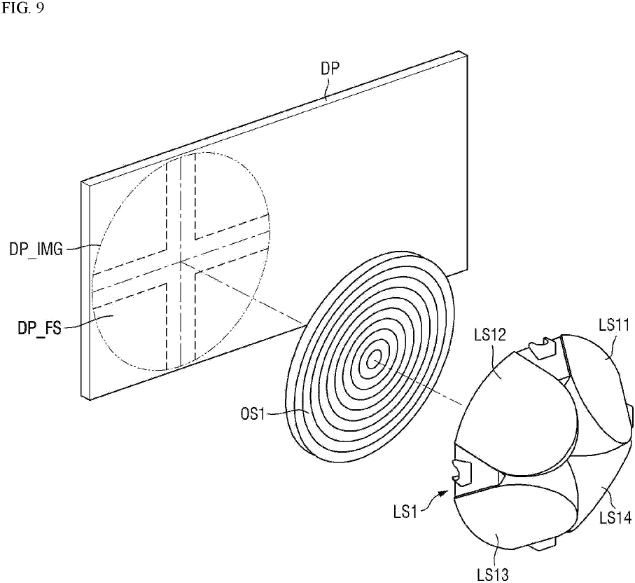

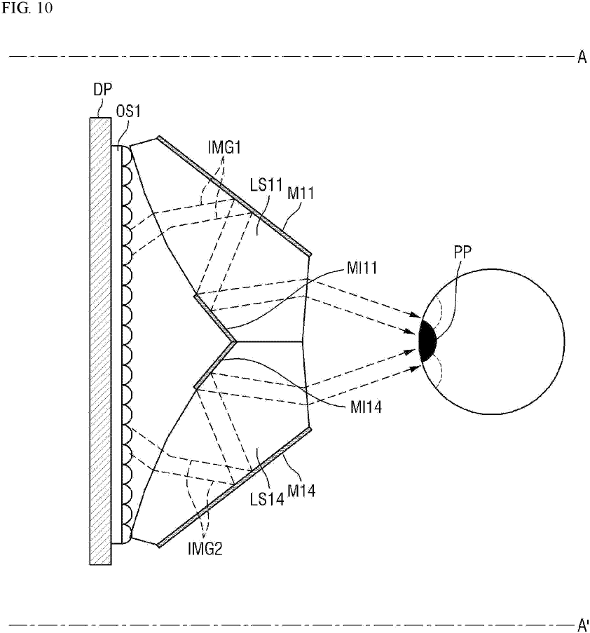

FIG. 9 is an exploded perspective view showing the structure that the display panel, the lens frame and the multi-channel lens shown in FIGS. 1 and 5 are disposed and coupled with one another. FIG. 10 is a cross-sectional view showing in detail the display device shown in FIG. 5, taken along line A - A′.

Referring to FIGS. 9 and 10, in an embodiment, the first and second lens frames OS1 and OS2 may be attached on the left-eye display surface and the right-eye display surface of the display panel DP, respectively. The first and second multi-channel lenses LS1 and LS2 may be attached on the front surfaces of the first and second lens frames OS1 and OS2, respectively.

Assuming that a user gazes straight at a display image DP_IMG and/or a virtual reality (VR) image to be described later through the first and second multi-channel lenses LS1 and LS2, the display panel DP displays the display image DP_IMG associated with the direction of the user’s pupils PP on the left-eye and right-eye image display surfaces.

In such an embodiment, the plurality of subsidiary lenses LS11, LS12, LS13, LS14, LS21, LS22, LS23 and LS24 formed on the first and second multi-channel lenses LS1 and LS2 may provide a plurality of channels through which light output from the front surface DP_FS of the display panel DP passes. Image display lights output from different parts of the front surface DP_FS of the display panel DP may pass through the channels via different paths. Herein, each image display light may include partial video and/or partial image for forming a single complete VR image.

In an embodiment, for example, as shown in FIG. 10, the first subsidiary lens LS11 may provide channels through which image display lights IMG1 output from a part of the display panel DP (e.g., the upper end of the display panel DP) pass. The fourth subsidiary lens LS14 may provide channels through which image display lights IMG2 output from another part of the display panel DP (e.g., the lower end of the display panel DP) pass. The part and the another part of the display panel DP may include an area overlapping the first subsidiary lens LS11 and an area overlapping the fourth subsidiary lens LS14.

In such an embodiment, although not shown in the drawings, the second subsidiary lens LS12 and the third subsidiary lens LS13 may provide channels through which lights output from different parts of the display panel DP pass.

According to an embodiment of the disclosure, the image display lights passing through the subsidiary lens LS11, LS12, LS13, LS14, LS21, LS22, LS23 and LS24 may be provided to the user after they have been reflected twice by the first to fourth mirror-coated parts M11, M12, M13 and M14 and the first to fourth inner coated parts MI11, MI12, MI13 and MI14. It should be understood, however, that the disclosure is not limited thereto.

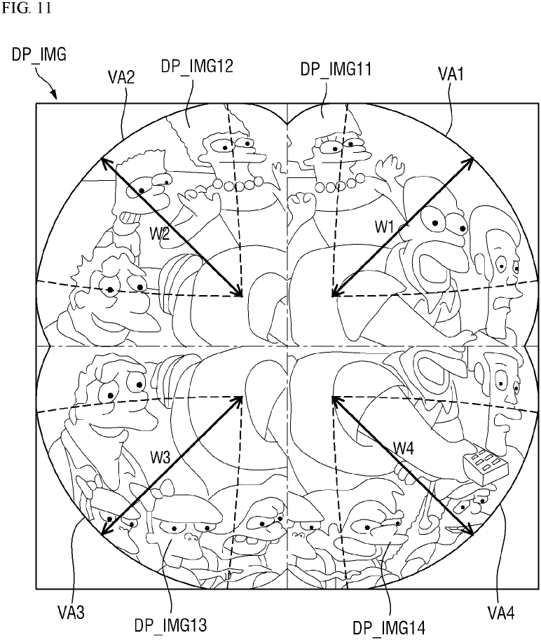

FIG. 11 is a view showing an image displayed on a display panel when a user’s pupil is located at the center. FIG. 12 is a view showing a VR image recognized by the user when a user’s pupil is located at the center.

Referring to FIG. 11, the display panel DP may display a display image DP_IMG divided into four display images DP_IMG11, DP_IMG12, DP_IMG13, and DP_IMG14. When viewed from the front surface DP_FS of the display panel DP, the display image DP_IMG may include a first divided display image DP_IMG11, a second divided display image DP_IMG12, a third divided display image DP_IMG13 and a fourth divided display image DP_IMG14 which are arranged in the counterclockwise direction with respect to the center of the display image DP_IMG.

When the user’s pupil PP substantially looks at the center, the first divided display image DP_IMG11, the second divided display image DP_IMG12, the third divided display image DP_IMG13 and the fourth divided display image DP_IMG14 may be displayed to have about a same size as each other. The size of the divided display images DP_IMG may refer to the width in the radial direction (diagonal direction) with respect to the center of the display images DP_IMG. It should be understood, however, that the disclosure is not limited thereto. The size may refer to the width in the horizontal direction and/or the width in the vertical direction when viewed from the top.

As shown in FIG. 11, the size of the first divided display image DP_IMG11, the size of the second divided display image DP_IMG12, the size of the third divided display image DP_IMG13 and the size of the fourth divided display image DP_IMG14 may be measured with respect to the boundaries of a first divided viewing area VA1, a second divided viewing area VA2, a third divided viewing area VA3, and a fourth divided viewing area VA4. It should be understood, however, that the disclosure is not limited thereto. The size of the first divided display image DP_IMG11, the second divided display image DP_IMG12, the third divided display image DP_IMG13 and the fourth divided display image DP_IMG14 may be measured with respect to the intersections of the boundaries therebetween.

As shown in FIG. 11, a first width W1 of the first divided display image DP_IMG11, a second width W2 of the second divided display image DP_IMG12, a third width W3 of the third divided display image DP_IMG13, and a fourth width W4 of the fourth divided display image DP_IMG14 may be substantially equal to each other. Accordingly, the first divided display image DP_IMG11, the second divided display image DP_IMG12, the third divided display image DP_IMG13 and the fourth divided display image DP_IMG14 may be displayed on the display panel DP at substantially a same magnification as each other.

Referring again to FIG. 12, the display device 10 may output a foveated-rendered VR image IMG_V to the display panel DP based on the position of the user’s pupil PP. Herein, the foveated rendering is one of the rendering techniques which reduces the rendering workload by increasing the image quality of a gaze zone while greatly reducing the image quality in the peripheral vision. Specifically, the foveated rendering may refer to an image processing scheme that gives a user an immersive, high-quality VR experience while reducing graphics computing load by way of displaying only the zone where the user gazes at the maximum image quality and other zones at lower image quality. In addition, the VR image IMG_V may refer to an image and/or a video recognized by the user through the first and second multi-channel lenses LS1 and LS2. Referring to FIGS. 11 and 12, a VR image IMG_V may be generated by combining parts of the plurality of divided display images DP_IMG11, DP_IMG12, DP_IMG13 and DP_IMG14.

In an embodiment, the first divided display image DP_IMG11, the second divided display image DP_IMG12, the third divided display image DP_IMG13 and the fourth divided display image DP_IMG14 may include the first divided viewing area VA1, the second divided viewing area VA2, the third divided viewing area VA3, and the fourth divided viewing area VA4, respectively.

The first divided viewing area VA1, the second divided viewing area VA2, the third divided viewing area VA3 and the fourth divided viewing area VA4 may be defined by, for example, the optical characteristics of the first and second multi-channel lenses LS1 and LS2 and the user’s gaze direction. The shapes, sizes and/or magnifications of the first divided viewing area VA1, the second divided viewing area VA2, the third divided viewing area VA3 and the fourth divided viewing area VA4 may vary depending on the optical characteristics of the first and second multi-channel lenses LS1 and LS2 and the user’s gaze direction.

When the user’s pupil PP is located substantially at the central point, the display panel DP may display the display image DP_IMG so that the magnification at the central region of the display image DP_IMG is greater than that of the peripheral region of the display image DP_IMG surrounding the central region.

As shown in FIG. 12, the central region of the VR image IMG_V may have a relatively high density of the pixels PX than the peripheral region surrounding the central region. In this instance, the density of pixels PX may increase as being from the edge of the VR image IMG_V toward the center of the VR image IMG_V. Accordingly, the central region of the VR image IMG_V may be displayed with a higher image quality than the peripheral region.

The central region of the VR image IMG_V may refer to the intersections of the boundaries between the image of the first divided viewing area VA1, the image of the second divided viewing area VA2, the image of the third divided viewing area VA3 and the image of the fourth divided viewing area VA4 which are recognized by being combined by the user, and nearby regions surrounding them. It should be understood, however, that the disclosure is not limited thereto.

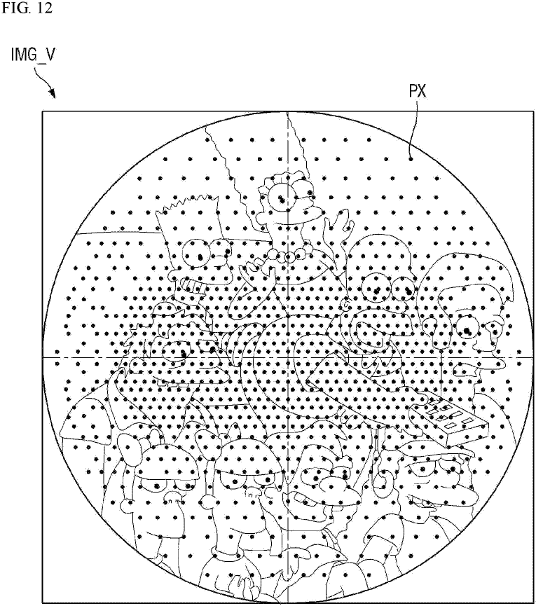

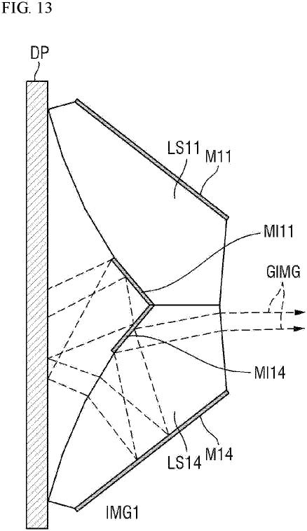

FIG. 13 is a cross-sectional view for illustrating display paths of ghost images in a display device and the causes.

As shown in FIG. 13, the first to fourth mirror-coated parts M11, M12, M13 and M14 of the first to fourth subsidiary lenses LS11, LS12, LS13 and LS14 formed in the first multi-channel lens LS1, respectively, reflect the image display lights incident from the rear surface toward the central concaved portion, i.e., the first to fourth inner coated parts MI11, MI12, MI13 and MI14.

The image display lights incident from the rear surface, i.e., the image display lights output from the front surface DP_FS of the display panel DP have to be applied to the first to fourth mirror-coated parts M11, M12, M13 and M14 to form the paths by being reflected by the first to fourth mirror-coated parts M11, M12, M13 and M14. However, if the image display lights output from the display panel DP are reflected off the rear surfaces of the first to fourth inner coated parts MI11, MI12, MI13 and MI14, undesired optical paths are formed, and accordingly ghost images may be seen.

In view of the above, according to an embodiment of the disclosure, the first lens frame OS1 is provided to prevent the image display lights output the display panel DP from being applied to the rear surfaces of the first to fourth inner coated parts MI11, MI12, MI13 and MI14. In such an embodiment, the image display lights passing through the first lens frame OS1 are refracted in the outward direction (or toward the outer periphery) of the first lens frame OS1.

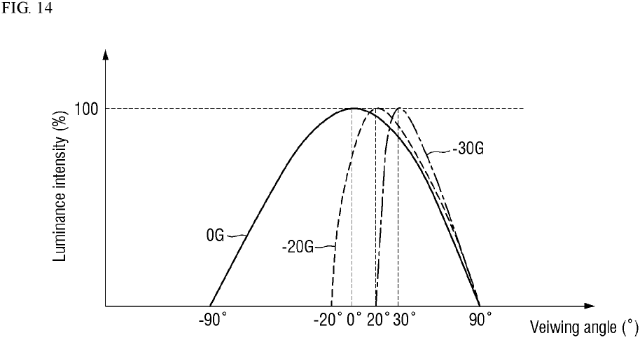

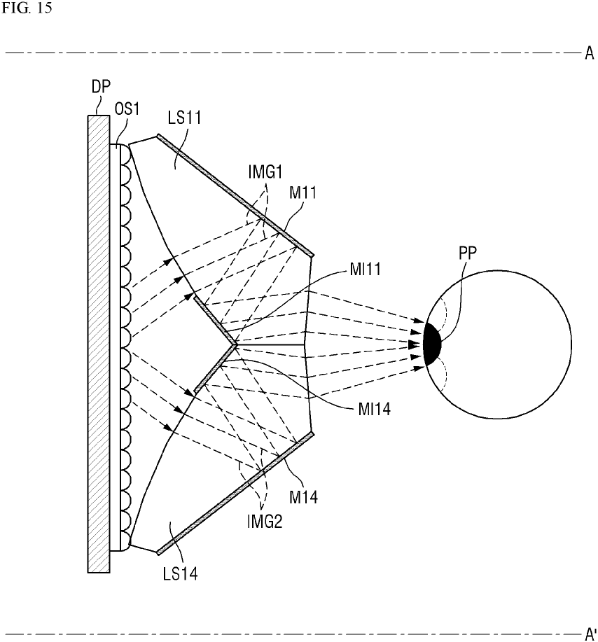

FIG. 14 is a graph for illustrating refraction angles of image display lights according to the lens frame structure of FIGS. 3 and 4. FIG. 15 is a cross-sectional view showing the refraction angles of image display lights and display paths according to the lens frame structure of FIGS. 3 and 4.

Referring to FIG. 14, the viewing angle of the image display lights passing through the first lens frame OS1 may be changed according to the refraction angle in the outward direction or the refractive index of the first lens frame OS1.

For example, a plurality of optical lenses Lp or a plurality of reflective partition walls Wp formed on the first lens frame OS1 may have one of first to third refractive indices 0 G, -20 G and -30 G toward the outer periphery of the first lens frame OS1. Accordingly, the first lens frame OS1 may refract the image display lights at an angle of about 1 degree (1°) to about 30 degrees (30°) according to one of the first to third refractive indices 0 G, -20 G and -30 G to output the image display lights. The viewing angles of the image display lights output through the first lens frame OS1 may be in a range of about -90° to about 90° depending on the hemispherical shape. However, if the image display lights are refracted at one of about 1 degree (1°) to about 30 degrees (30°) through the first lens frame OS1, the viewing angles may be changed in a range of about -20° to about 90°.

As shown in FIG. 15, the image display lights refracted at the angle of about 20° in the outward direction at the first lens frame OS1 may not be applied to the rear surfaces of the first to fourth inner coated parts MI11, MI12, MI13 and MI14. Accordingly, the image display lights refracted at the angle of about 20° in the outward direction at the first lens frame OS1 are reflected off the first to fourth mirror-coated parts MI11, MI12, MI13, MI14 of the first to fourth subsidiary lens LS11, LS12, LS13 and LS1, and then are applied to the first to fourth inner coated parts MI11, MI12, MI13 and MI14. Then, the first to fourth inner coated parts MI11, MI12, MI13 and MI14 may reflect again the image display lights reflected from the first to fourth mirror-coated parts M11, M12, M13 and M14 toward the user’s eyes on the front side.

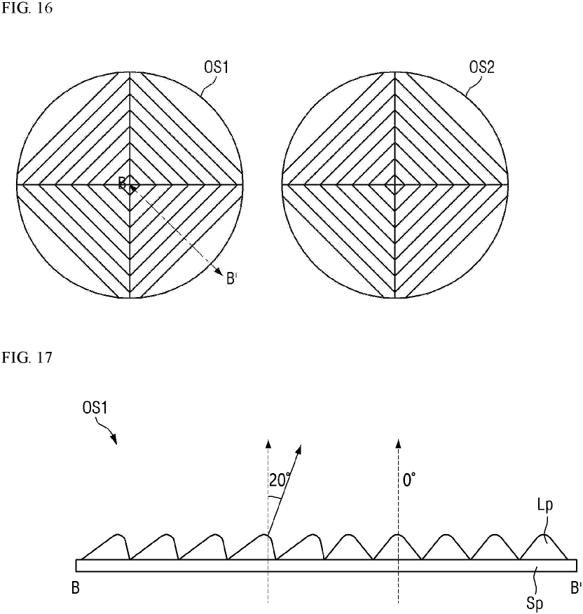

FIG. 16 is a front view showing a structure of a lens frame according to an alternative embodiment of the disclosure. FIG. 17 is a cross-sectional view showing an example of the lens frame shown in FIG. 16, taken along line B - B′.

Referring to FIGS. 16 and 17, a lens frame includes a plurality of optical lenses Lp that refracts image display lights passing through a lens sheet Sp in the outward direction (or toward the outer periphery) of the lens sheet Sp to output the image display lights.

In such an embodiment, each of the plurality of optical lenses Lp is formed in a bar type and disposed to cover the front surface of the lens sheet Sp. The plurality of optical lenses Lp may be disposed in first to fourth divided areas of the lens sheet Sp in a diagonal direction with respect to the center of the lens sheet Sp. The first to fourth divided areas of the lens sheet Sp may correspond to the first to fourth divided viewing areas VA1 to VA4 of the display panel DP, respectively, in which the first to fourth divided display images DP_IMG11 to DP_IMG14 are respectively displayed.

Adjacent optical lenses Lp may have different areas, lengths or widths from each other. In addition, the cross section of each of the plurality of optical lenses Lp may be formed in a convex protruding shape, e.g., a hemispherical shape, so that the image display light incident through the lens sheet Sp on the rear side may be radially emitted on the front side.

In an embodiment, referring to FIG. 17, the plurality of optical lenses Lp comprises a plurality of first optical lenses formed such that the highest point (or the thickest point) of the convex protruding cross-section, e.g., the hemispherical cross-section, is disposed at a position inclined at a first angle, and a plurality of second optical lenses formed in a convex protruding shape such that the highest point (or the thickest point) is not inclined in the front direction.

In such an embodiment, for each of the plurality of first optical lenses among the plurality of optical lenses Lp, the highest point of the convex protruding cross-section, e.g., the hemispherical cross-section, has an inclination that is inclined by a first angle (e.g., about 20°) in the outward direction from the front vertical direction (the dotted arrow) of each optical lens Lp. Each of the first optical lens is formed such that the thickest point is located at the point that is inclined by the first angle with respect to the front vertical direction (the dotted arrow) toward the outer periphery of the lens sheet Sp. Due to the cross-sectional shape and the inclination angle of each first optical lens, each optical lens Lp may refract the image display light by the first angle to output the image display light toward the outer periphery of the lens sheet Sp. The plurality of first optical lenses may be disposed in a predetermined nearby region close to the center of the lens sheet Sp.

In such an embodiment, each of the plurality of second optical lenses among the plurality of optical lenses Lp is formed in a convex protruding shape such that the highest point (or the thickest point) of the convex protruding cross-section is located in the front vertical direction of each optical lens Lp (the dotted arrow). The plurality of second optical lenses may be disposed in a predetermined nearby region close to the periphery of the lens sheet Sp. Due to the cross-sectional shape of the second optical lenses, the image display lights may be radiated in the front direction of the lens sheet Sp.

FIG. 18 is a cross-sectional view showing another example of the lens frame shown in FIG. 16, taken along line B - B′.

Referring to FIG. 4, each of the first and second lens frames OS1 and OS2 may be implemented as a flat light-transmitting film Fp that includes a plurality of reflective partition walls Wp or a plurality of reflective bonding surfaces inclined at a predetermined angle. The light-transmitting film Fp may refract and reflect the image display lights incident on the rear side in the outward direction (or toward the outer periphery) of the flat light-transmitting film Fp according to the refractive index depending on its material and the inclinations of the plurality of reflective partition walls Wp or the reflective bonding surfaces to output the image display lights.

In such an embodiment, the plurality of reflective partition walls Wp or the plurality of reflective bonding surfaces included in the light-transmitting film Fp may be formed in a straight bar type, and may be arranged in a diagonal direction with respect to the center of the light-transmitting film Fp in the first to fourth divided areas of the light-transmitting film Fp. The first to fourth divided areas of the light-transmitting film Fp may correspond to the first to fourth divided viewing areas VA1 to VA4 of the display panel DP, respectively, in which the first to fourth divided display images DP_IMG11 to DP_IMG14 are respectively displayed. Adjacent bar-type reflective partition walls Wp or the reflective bonding surfaces may have different distances and the lengths from each other.

In such an embodiment, referring to FIG. 18, the plurality of reflective partition walls Wp includes a plurality of first partition walls inclined at a first angle (e.g., about 20°) in the outward direction from the front vertical direction (the dotted arrow), and a plurality of second partition walls not inclined from the front vertical direction but formed vertically in parallel to the front vertical direction.

The plurality of first partition walls among the plurality of reflective partition walls Wp may be inclined at the predetermined first angle toward the outer periphery with respect to the front vertical direction (the dotted arrow). The first and second lens frames OS1 and OS2 may refract image display lights at the first angle in the outer direction according to the inclination angle and spacing of the plurality of first partition walls to output the image display lights. The plurality of first partition walls may be disposed in a predetermined nearby region close to the center of the light-transmitting film Fp.

In such an embodiment, the plurality of second partition walls among the plurality of reflective partition walls Wp is formed vertically in parallel to the front vertical direction (the dotted arrow) of the light-transmitting film Fp. The plurality of second partition walls may be disposed in a predetermined outer region close to the periphery of the light-transmitting film Fp. As the second partition walls are disposed vertically, the image display lights may be radiated in the front direction of the light-transmitting film Fp.

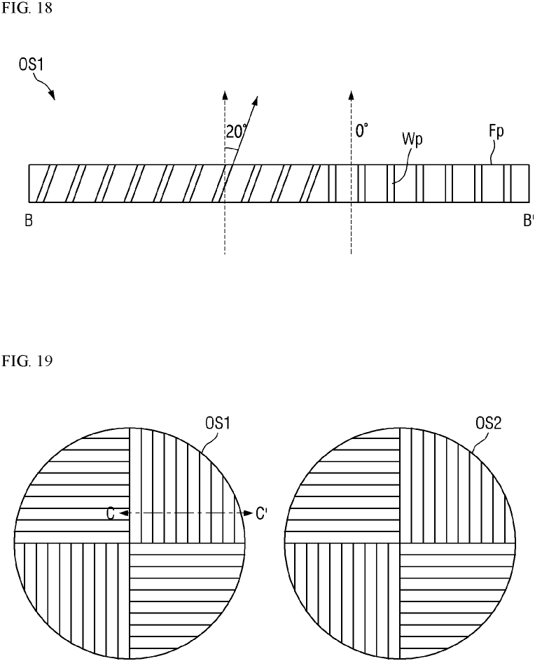

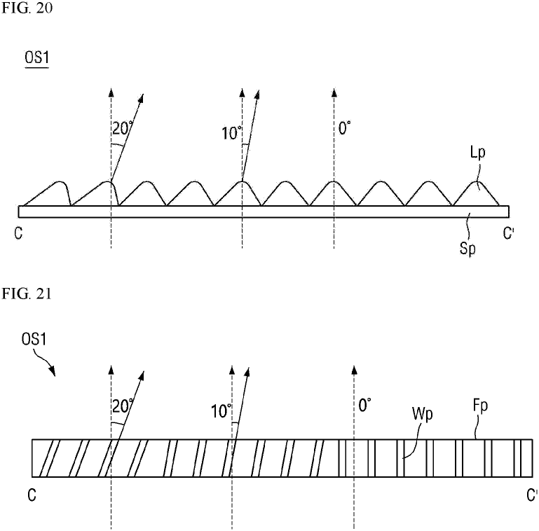

FIG. 19 is a front view showing a structure of a lens frame according to yet another embodiment of the disclosure. FIG. 20 is a cross-sectional view showing an example of the lens frame shown in FIG. 19, taken along line C - C′.

Referring to FIGS. 19 and 20, each of the plurality of optical lenses Lp is formed in a bar type and disposed to cover the front surface of the lens sheet Sp, and may be disposed in each of the first to fourth divided areas of the lens sheet Sp in the form of horizontal or vertical stripes. The first to fourth divided areas of the lens sheet Sp may correspond to the first to fourth divided viewing areas VA1 to VA4 of the display panel DP, respectively, in which the first to fourth divided display images DP_IMG11 to DP_IMG14 are respectively displayed. In addition, the optical lenses Lp arranged in each of the first to fourth divided areas may be arranged in parallel in the vertical direction or in the horizontal direction in each of the first to fourth divided areas. In an embodiment, for example, the optical lenses Lp may be arranged in parallel in the vertical direction in the first and third divided areas, and the optical lenses Lp may be arranged in parallel in the horizontal direction in the second and fourth areas.

Adjacent optical lenses Lp may have different areas, lengths or widths from each other. In addition, the cross section of each of the plurality of optical lenses Lp may be formed in a convex protruding shape, e.g., the hemispherical cross-section, so that the image display light incident through the lens sheet Sp on the rear side may be radially emitted on the front side.

In such an embodiment, referring to FIG. 20, the plurality of optical lenses Lp comprises a plurality of first optical lenses formed such that the highest point (or the thickest point) of the convex protruding cross-section is disposed at a position inclined at a first angle, and a plurality of second optical lenses formed in a convex protruding shape such that the highest point of the cross section is disposed on the front surface and is not inclined in the front direction. In addition, the plurality of optical lenses Lp further include a plurality of third optical lenses formed so that the highest point of the cross-section is disposed at a position inclined at a second angle.

In such an embodiment, for each of the plurality of first optical lenses among the plurality of optical lenses Lp, the highest point of the convex protruding cross-section, e.g., the hemispherical cross-section, is disposed at a position that is inclined by a first angle (e.g., about 20°) in the outward direction from the front vertical direction (the dotted arrow) of each optical lens Lp.

In an embodiment, each of the plurality of second optical lenses among the plurality of optical lenses Lp is formed in a convex protruding shape, e.g., the hemispherical cross-section, such that the highest point (or the thickest point) of the convex protruding cross-section is located in the front vertical direction of each optical lens Lp (the dotted arrow). The plurality of second optical lenses may be disposed in a predetermined nearby region close to the periphery of the light-transmitting film Fp. Due to the cross-sectional shape of the second optical lenses Lp, the image display lights may be radiated in the front direction of the lens sheet Sp.

In an embodiment, for each of the plurality of third optical lenses among the plurality of optical lenses Lp, the highest point the convex protruding cross-section is disposed at a position that is inclined by a second angle (e.g., about 10°) in the outward direction from the front vertical direction (the dotted arrow) of each optical lens Lp. In an embodiment, each of the third optical lens is formed such that the thickest point is inclined by the second angle with respect to the front vertical direction (the dotted arrow) toward the outer periphery of the lens sheet Sp. The second angle (e.g., about 10°) may be smaller than the first angle (e.g., about 20°). Due to the cross-sectional shape and the inclination angle of each third optical lens, each of the third optical lens may refract the image display lights by the second angle toward the outer periphery of the lens sheet Sp to output the image display lights. The plurality of third optical lenses may be disposed between the nearby region in which the plurality of first optical lenses is disposed and the outer region in which the plurality of second optical lenses is disposed.

FIG. 21 is a cross-sectional view showing another example of the lens frame shown in FIG. 19, taken along line C - C′.

Referring to FIG. 21, each of the first and second lens frames OS1 and OS2 may be implemented as a flat light-transmitting film Fp that includes a plurality of reflective partition walls Wp inclined at a predetermined angle. The light-transmitting film Fp may refract and reflect the image display lights incident on the rear side toward the outer periphery of the light-transmitting film Fp according to the refractive index depending on its material and the inclinations of the plurality of reflective partition walls Wp to output the image display lights.

In such an embodiment, the plurality of reflective partition walls Wp included in the light-transmitting film Fp may be formed in a straight bar type, and may be disposed in the form of horizontal or vertical stripes for each of the first to fourth divided areas of the light-transmitting film Fp. In addition, the plurality of reflective partition walls Wp arranged in each of the first to fourth divided areas may be arranged in parallel in the vertical direction or in the horizontal direction in each of the first to fourth divided areas. In an embodiment, for example, the reflective partition walls Wp may be arranged in parallel in the vertical direction in the first and third divided areas, and the reflective partition walls Wp may be arranged in parallel in the horizontal direction in the second and fourth areas. Adjacent bar-type reflective partition walls Wp may have different distances and the lengths from each other.

In an embodiment, referring to FIG. 21, the plurality of reflective partition walls Wp includes a plurality of first partition walls inclined at a first angle (e.g., about 20°) in the outward direction from the front vertical direction (the dotted arrow), a plurality of second partition walls not inclined from the front vertical direction but formed vertically in parallel to the front vertical direction, and a plurality of third partition walls inclined at a second angle (e.g., about 10°) toward the outer periphery from the front vertical direction (the dotted arrow).

The plurality of first partition walls among the plurality of reflective partition walls Wp may be inclined at the predetermined first angle toward the outer periphery with respect to the front vertical direction (the dotted arrow). The first and second lens frames OS1 and OS2 may refract image display lights at the first angle in the outward direction according to the inclination angle and spacing of the plurality of first partition walls to output the image display lights. The plurality of first partition walls may be disposed in a predetermined nearby region close to the center of the light-transmitting film Fp.

In an embodiment, the plurality of second partition walls among the plurality of reflective partition walls Wp is formed vertically in parallel to the front vertical direction (the dotted arrow) of the light-transmitting film Fp. The plurality of second partition walls may be disposed in a predetermined outer region close to the periphery of the light-transmitting film Fp. As the second partition walls are disposed vertically, the image display lights may be radiated in the front direction of the light-transmitting film Fp.

The plurality of third partition walls among the plurality of reflective partition walls Wp may be inclined at the predetermined second angle toward the outer periphery with respect to the front vertical direction (the dotted arrow). The second angle (e.g., about 10°) may be smaller than the first angle (e.g., about 20°). The first and second lens frames OS1 and OS2 may refract image display lights at the second angle toward the outer periphery according to the inclination angle and spacing of the plurality of second partition walls to output the image display lights. The plurality of second partition walls may be disposed between the nearby region in which the plurality of first partition walls is disposed and the outer region in which the plurality of second partition walls is disposed.

In embodiments of the invention, the display device 10 including the structural features as described above may improve user satisfaction and reliability by preventing image display defects such as a ghost image.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a display panel which displays an image on an image display surface thereof;
at least one lens frame disposed on the image display surface, wherein the at least one lens frame refracts image display lights emitted from the image display surface; and
at least one multi-channel lens which forms exit paths of the image display lights refracted by the at least one lens frame for each of multiple channels.

2. The display device of claim 1, wherein the at least one lens frame comprises first and second lens frames disposed in line with positions of a user’s left and right eyes, respectively, and
wherein the first and second lens frames refract the image display lights output from the image display surface of the display panel toward a front side at a predetermined angle in an outward direction or toward an outer periphery to output the image display lights to rear surfaces of the at least one multi-channel lenses.

3. The display device of claim 2, wherein the at least one multi-channel lens comprises first and second multi-channel lenses disposed in line with the first and second lens frames, respectively, and
wherein the first and second multi-channel lenses pass the image display lights refracted by the first and second lens frames through different paths for the multiple channels, to transmit the image display lights to the user’s left and right eyes through channels of the different paths.

4. The display device of claim 2, wherein each of the first and second lens frames comprises
a lens sheet having an area and a shape corresponding to the image display surface of the display panel; and
a plurality of optical lenses disposed on a front surface of the lens sheet, wherein the plurality of optical lenses refracts the image display lights passed through the lens sheet in an outward direction or toward an outer periphery of the lens sheet to output the image display lights.

5. The display device of claim 4, wherein the plurality of optical lenses is formed in a ring type having different circumferences from each other, and is arranged in a form of a plurality of concentric circles on the front surface of the lens sheet to cover the front surface of the lens sheet.

6. The display device of claim 4, wherein one or more structural characteristics of length, area and width of adjacent optical lenses of the plurality of optical lenses are different from each other.

7. The display device of claim 4, wherein each of the plurality of optical lenses has a convex protruding cross-section, and
wherein a highest point or a thickest point of the convex protruding cross-section is disposed at a position inclined at a first angle from a front vertical direction in the outward direction or toward the outer periphery.

8. The display device of claim 4, wherein
each of the plurality of optical lenses is in a bar type and disposed to cover the front surface of the lens sheet, and
wherein the plurality of optical lenses is arranged in parallel in a diagonal direction with respect to a center of the lens sheet in first to fourth divided areas of the lens sheet.

9. The display device of claim 4, wherein the plurality of optical lenses comprises
a plurality of first optical lenses, each having a convex protruding cross-section shaped in a way such that a highest point or a thickest point of the convex protruding cross-section is disposed at a position inclined at a first angle from a front vertical direction, and
a plurality of second optical lenses, each having a convex protruding cross-section shaped in a way such that a highest point or a thickest point of the convex cross-section is not inclined from the front vertical direction.

10. The display device of claim 4, wherein
each of the plurality of optical lenses is in a bar type and disposed to cover the front surface of the lens sheet, and
the plurality of optical lenses is arranged in parallel in a horizontal or vertical stripes in first to fourth divided areas of the lens sheet.

11. The display device of claim 4, wherein the plurality of optical lenses comprises
a plurality of first optical lenses, each having a convex protruding cross-section shaped in a way such that a highest point or a thickest point of the convex protruding cross-section is disposed at a position inclined at a first angle from a front vertical direction,
a plurality of second optical lenses, each having a convex protruding cross-section shaped in a way such that a highest point or a thickest point of the convex protruding cross-section is not inclined from the front vertical direction, and
a plurality of third optical lenses, each having a convex protruding cross-section shaped in a way such that a highest point or a thickest point of the convex protruding cross-section is disposed at a position inclined at a second angle different from the first angle from the front vertical direction.

12. The display device of claim 2, wherein
each of the first and second lens frames comprises a flat light-transmitting film comprising a plurality of reflective partition walls or a plurality of reflective bonding surfaces inclined at a predetermined angle, and
each of the first and second lens frames refracts or reflects the image display lights incident on a rear surface in the outward direction or toward the outer periphery from a center by inclinations of the plurality of reflective partition walls or the plurality of reflective bonding surfaces.

13. The display device of claim 12, wherein
the plurality of reflective partition walls or the plurality of reflective bonding surfaces is in a ring type having different circumferences from each other, and
the plurality of reflective partition walls or the plurality of reflective bonding surfaces is arranged in a plurality of concentric circles inside the light-transmitting film.

14. The display device of claim 12, wherein one or more structural characteristics of spacing, length, thickness, area and width of the plurality of reflective partition walls or the plurality of reflective bonding surfaces are different from one another.

15. The display device of claim 12, wherein the plurality of reflective partition walls or the plurality of reflective bonding surfaces is inclined at a first angle in the outward direction or toward the outer periphery from a front vertical direction to refract the image display lights.

16. The display device of claim 12, wherein
the plurality of reflective partition walls or the plurality of reflective bonding surfaces is in a straight bar type, and
the plurality of reflective partition walls or the plurality of reflective bonding surfaces is arranged in parallel in a diagonal direction parallel with respect to a center in first to fourth divided areas of the light-transmitting film.

17. The display device of claim 12, wherein the plurality of reflective partition walls comprises:
a plurality of first partition walls inclined at a first angle from a front vertical direction to an outward direction; and
a plurality of second partition walls disposed vertically such that plurality of second partition walls is not inclined from the front vertical direction.

18. The display device of claim 12, wherein
the plurality of reflective partition walls or the plurality of reflective bonding surfaces is in a straight bar type, and
the plurality of reflective partition walls or the plurality of reflective bonding surfaces is arranged in horizontal or vertical stripes in each of first to fourth divided areas of the light-transmitting film.

19. The display device of claim 12, wherein the plurality of reflective partition walls comprises:
a plurality of first partition walls inclined at a first angle from a front vertical direction toward the outer periphery;
a plurality of second partition walls disposed vertically such that the plurality of second partition walls is not inclined from the front vertical direction; and
a plurality of third partition walls inclined at a second angle from the front vertical direction toward the outer periphery.

20. A wearable device comprising:
a main frame mounted on a user’s body;
a display device mounted on the main frame, wherein the display device displays an image; and
a cover frame covering the display device,
wherein the display device comprises:
a display panel which displays the image on an image display surface thereof;
at least one lens frame disposed on the image display surface, wherein the at least one lens frame refracts image display lights emitted from the image display surface; and
at least one lens which forms exit paths of the image display lights refracted by the at least one lens frame for each of multiple channels.
